(19) United States
(12) Patent Application Publication
(10) Pub. No.: US 2025/0085401 A1
(43) Pub. Date: Mar. 13, 2025

(54) LIDAR SYSTEMS WITH MEMS MICROMIRRORS AND MICROMIRROR ARRAYS

(71) Applicant: Preciseley Microtechnology Corporation, Burnaby (CA)

(72) Inventors: Tiansheng ZHOU, Edmonton (CA); Qiuyang XIONG, Edmonton (CA); Lawrence LAM, Edmonton (CA); Daniel MILDENBERGER, Edmonton (CA); Zhiwei ZHOU, Edmonton (CA)

(73) Assignee: Preciseley Microtechnology Corporation, Burnaby, BC (CA)

(21) Appl. No.: 18/361,292

(22) PCT Filed: Jan. 28, 2022
(86) PCT No.: PCT/CA2022/050124

§ 371 Date: Jul. 28, 2023

Related U.S. Application Data
(60) Provisional application No. 63/143,018, filed on Jan. 28, 2021.

(51) Int. Cl. G01S 7/481

(52) U.S. Cl. CPC G01S 7/4816; G01S 7/4817

(57) ABSTRACT

A Light Detection and Ranging (LiDAR) system, comprising: a light emitting unit comprising a light source comprising one or more laser emitters for generating one or more laser beams for producing reflected photons off of a target; a scanning unit comprising a Micro-Electro-Mechanical Systems (MEMS) mirror for changing an outgoing direction of the one or more laser beams; a light receiving unit comprising a MEMS mirror array and a plurality of photon detectors, the MEMS mirror array being configured to deflect the reflected photons to the plurality of photon detectors; and a control system for controlling the LiDAR system, the control system being configured to adjust the MEMS mirror and the MEMS mirror array.

### TECHNICAL FIELD

The following relates to MEMS (Micro-Electro-Mechanical systems) micromirrors and micromirror arrays, particularly for LiDAR Applications.

### BACKGROUND

MEMS (Micro-Electro-Mechanical Systems) mirrors and mirror arrays have several applications such as, for example, fiber optic networks in optical switches, optical attenuators, and optical tunable filters. High filling factor MEMS mirror arrays formed by mirrors rotatable in one- and two-dimensions have particular importance in wavelength division multiplexing systems. For example, they may be used as Optical Cross-Connection (OXC) switches, and Wavelength Selective Switches (WSS). The filling factor is generally defined as the ratio of the active, or reflective mirror area to the total area of an array. A high filling factor may improve optical channel shape and reduce optical loss in a system. A micromirror that is one- or two-dimensionally rotatable may provide switching of the optical beam between the optical channels while reducing or avoiding undesirable optical transient cross-talk during switching, and also may provide variable optical attenuations.

MEMS mirrors and mirror arrays also have been applied in LiDAR (Light Detection and Ranging) for steering the outgoing laser beam and guiding the returned laser beam to the sensitive detectors. However, mechanical scanning LiDAR systems use conventional electrical motors to steer the laser beams. These motors tend to be heavy, power intensive and prone to wearing and tearing.

Implementation of MEMS mirrors in autonomous vehicle LiDAR systems may be less expensive, more reliable and more energy efficient as opposed to conventional LiDAR systems. To achieve a signal to noise ratio and detection range suitable for the requirements of autonomous vehicle LiDAR, larger MEMS mirrors, e.g., of over 10 mm in diameter, may be necessary. However, larger MEMS mirrors may have difficulty achieving high tilting angles and scanning speeds, and may dynamically deform to a greater extent. It follows that it may be difficult for MEMS mirrors of such dimensions to meet the vibration and shock standards required for use in autonomous vehicle LiDAR.

In view of the foregoing, it is desirable to develop improved LiDAR systems.

### SUMMARY

In one aspect, provided is a light receiving unit configured to be used in a Light Detection and Ranging (LiDAR) system, the light receiving unit comprising: a MEMS mirror array including a plurality of receiving mirrors, the MEMS mirror array being configured to deflect reflected photons, produced by a scanning unit, to a plurality of photon detectors, the MEMS mirror array being controllable by a control system that is configured to control the scanning unit and the light receiving unit.

In an implementation, the light receiving unit further comprises the plurality of photon detectors and a lens system for focusing the reflected photons on the plurality of photon detectors.

In another implementation, the positions of the MEMS mirror are detectable by electrical sensors using electrical sensing elements configured to send data to the control system.

In yet another implementation, the electrical sensing elements comprise piezoresistive, piezoelectric or capacitive sensing elements.

In yet another implementation, the light receiving unity further comprises a light diffusing device positioned between the lens system and the plurality of detectors.

In yet another implementation, the light receiving unit is further configured to rotate the mirrors in the MEMS mirror array synchronously to a predefined angle at a predefined time to deflect photons reflected from one of the scanning lines.

In yet another implementation, the receiving mirrors are rotatable in one dimension (1D) and/or in two dimensions (2D), and are controllable by the control system to rotate independently or collectively.

In yet another implementation, the receiving mirrors of the MEMS mirror array are defined by a long edge and a short edge, and the mirrors are positioned parallel to one another along the long edge, a rotation axis of the MEMS mirror array is parallel to the long edge.

In yet another implementation, the receiving mirrors in the MEMS array are arranged in a 2D mirror array, and each of the mirrors has two rotation axes.

In another aspect, provided is a Light Detection and Ranging (LiDAR) system, comprising: a light emitting unit comprising a light source comprising one or more laser emitters for generating one or more laser beams for producing reflected photons off of a target; a scanning unit comprising a scanning mirror for changing an outgoing direction of the one or more laser beams; a light receiving unit comprising a MEMS mirror array including a plurality of receiving mirrors and a plurality of photon detectors, the MEMS mirror array being configured to deflect the reflected photons to the plurality of photon detectors; and a control system for controlling the LiDAR system, the control system being configured to adjust the scanning and receiving mirrors.

In an implementation, the control system comprises: at least one of a first axis control circuit and a second axis control circuit for adjusting the scanning and receiving mirrors; a light source control circuit configured to control the light emitting unit to modulate the one or more laser beams; a detector output process circuit configured to receive signals from the plurality of photon detectors; and a fault detection circuit configured to detect failure of the scanning unit, of the light receiving unit and/or of the plurality of photon detectors.

In another implementation, the scanning mirror is a MEMS mirror.

In yet another implementation, positions of the MEMS mirror are detectable by electrical sensors using electrical sensing elements configured to send position data to the control system.

In yet another implementation, the scanning mirror is a galvanometer-based scanning mirror.

In yet another implementation, the scanning unit further comprises an angle detection system comprising a second light source and a position sensor, wherein the second light source is configured to emit a detectable laser beam that is deflected by the scanning mirror and detected by the position sensor to obtain mirror position data, the position sensor being configured to send the mirror position data to the control system.

In yet another implementation, the scanning unit further comprises a second scanning mirror for directing the one or more laser beams to the scanning mirror.

In yet another implementation, the scanning and receiving mirrors are rotatable in one dimension (1D) and/or in two dimensions (2D), and are controllable by the control system to rotate independently or collectively.

In yet another implementation, the receiving mirrors of the MEMS mirror array are defined by a long edge and a short edge, and the mirrors are positioned parallel to one another along the long edge, a rotation axis of the MEMS mirror array is parallel to the long edge.

In yet another implementation, the receiving mirrors in the MEMS array are arranged in a 2D mirror array, and each of the mirrors has two rotation axes.

In yet another implementation, the scanning unit is configured to project a plurality of scanning lines onto a target.

In yet another implementation, the scanning unit is configured to project photons onto a plurality of scanning areas to detect a plurality of scanning points in each of the scanning areas.

In yet another implementation, the fault detection circuit is configured to receive and send to, in the form of electronic signals, the first axis control circuit and/or second axis control circuit, values corresponding to positions of the mirrors and/or environmental conditions including one or more of temperature, shock, and vibration, to enable the first and/or second axis control circuit to adjust the positions of the mirrors based on the values.

In yet another implementation, the LiDAR system further comprises a lens system configured to direct the reflected photons to the plurality of detectors, and a light diffusing device positioned between the lens system and the plurality of detectors.

In yet another implementation, the scanning MEMS mirror is part of the MEMS mirror array.

In yet another implementation, the scanning MEMS mirror is separate from the MEMS mirror array.

In yet another implementation, the scanning MEMS mirror and the MEMS mirror array are packaged together.

### BRIEF DESCRIPTION OF THE DRAWINGS

Embodiments will now be described by way of example only with reference to the appended drawings wherein:

FIGS. 1A and 1B are perspective views of a prior art microelectromechanical system (MEMS) two dimensional (2D) scanning micromirror, vertical comb drive actuators and a carrier wafer.

FIGS. 2A and 2B are perspective views of a prior art 2D micro mirror array design using a Through Silicon Via (TSV) carrier wafer.

FIG. 3 is a perspective view of a prior art MEMS one dimensional (1D) scanning micromirror.

FIG. 4 is a perspective view of a prior art MEMS 1D scanning micromirror array.

FIG. 5 is a schematic diagram of an example embodiment of a LiDAR system comprising the emitting/scanner unit and MEMS mirror array, a light emitting unit, a control system, a detector output process circuit and a fault detection circuit.

FIG. 6 is a schematic diagram of an example embodiment of the emitting unit shown in FIG. 5.

FIG. 7 is a schematic diagram of another example embodiment of the emitting unit shown in FIG. 5.

FIG. 8 is a schematic diagram of yet another example embodiment of the emitting unit shown in FIG. 5.

FIG. 9 is a schematic diagram of yet another example embodiment of the emitting unit shown in FIG. 5.

FIG. 10 is a perspective view of an example embodiment of a MEMS mirror array configuration which may be used in the LiDAR system shown in FIG. 5.

FIG. 11 is a perspective view of another example embodiment of a MEMS mirror array configuration which may be used in the LiDAR system shown in FIG. 5.

FIG. 12 is a perspective view of yet another example embodiment of a MEMS mirror array configuration which may be used in the LiDAR system shown in FIG. 5.

FIG. 13 is a schematic diagram illustrating reception of light by a single axis MEMS mirror array which may be implemented by the LiDAR system shown in FIG. 5.

FIG. 14 is a schematic diagram illustrating reception of light by a dual axis MEMS mirror array which may be implemented by the LiDAR system shown in FIG. 5.

FIG. 15 is a schematic diagram of an example embodiment of a coupling topology between the scanning unit and MEMS mirror array shown in FIG. 5, configured for dual axis scanning by the scanner and the MEMS mirror array.

FIG. 16 is a schematic diagram of another example embodiment of a coupling topology between the scanning unit and MEMS mirror array shown in FIG. 5, configured for dual axis scanning by the scanner and single axis scanning by the MEMS mirror array.

FIG. 17 is a schematic diagram of yet another example embodiment of a coupling topology between the scanning unit and MEMS mirror array shown in FIG. 5, configured for dual axis scanning by the scanner and single axis scanning by MEMS mirror array.

FIG. 18 is a schematic diagram showing an example embodiment of a configuration of the lens system and the photosensitive detector shown in FIG. 5.

FIG. 19 is a schematic diagram showing another example embodiment of a configuration of the lens system and the photosensitive detector shown in FIG. 5, the photosensitive detector being a 1D array with multiple detecting pixels.

FIG. 20 is a schematic diagram showing yet another example embodiment of a configuration of the lens system and the photosensitive detector shown in FIG. 5, the photosensitive detector being a 1D array with multiple photosensitive detecting pixels and comprising an optical diffusing device.

FIG. 21 is a schematic diagram showing yet another example embodiment of a configuration of the lens system and the photosensitive detector shown in FIG. 5, the photosensitive detector comprising an optical fiber bundle.

FIG. 22 is a schematic diagram showing another example embodiment of a configuration of the lens system and the photosensitive detector shown in FIG. 5, the photosensitive detector comprising a waveguide.

FIG. 23 is a schematic illustration of five different example embodiments of the optical diffusing devices which may be used.

FIG. 24 is a schematic diagram showing an example embodiment of a chip package including a MEMS mirror array.

FIG. 25 is a schematic diagram showing another example embodiment of a chip package including a single 2D MEMS scanning mirror and a MEMS mirror array.

### DETAILED DESCRIPTION

Implementation of MEMS mirror arrays in LiDAR systems, as described herein, may enable the use of a larger optical aperture with higher tilting angles, higher scanning speeds, reduced dynamic deformation, and reduced sensitivity to vibration and shock.

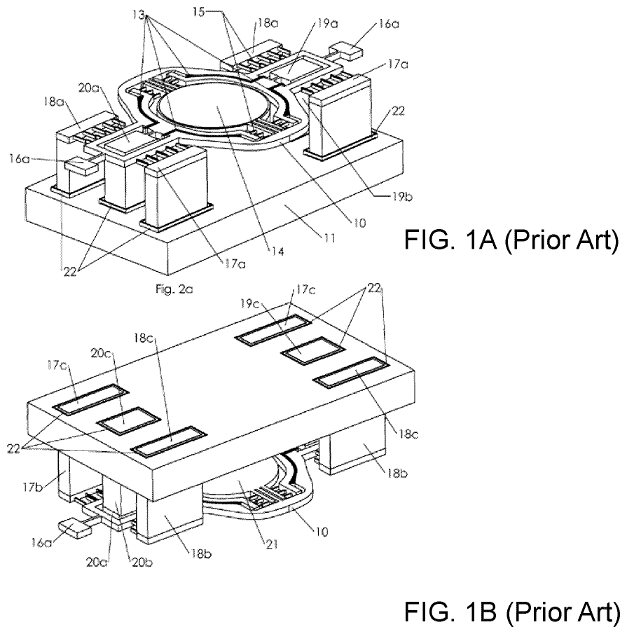

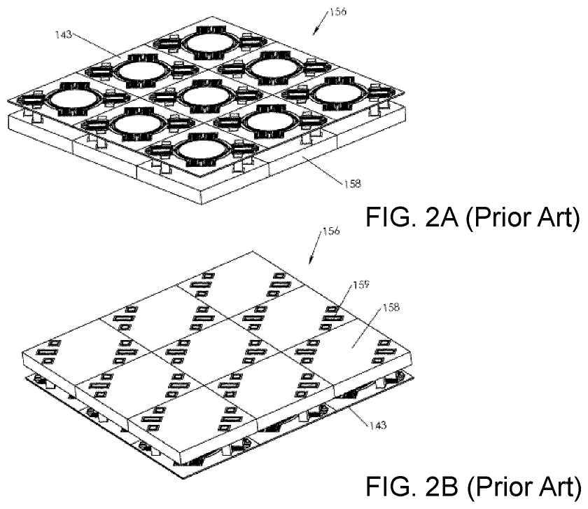

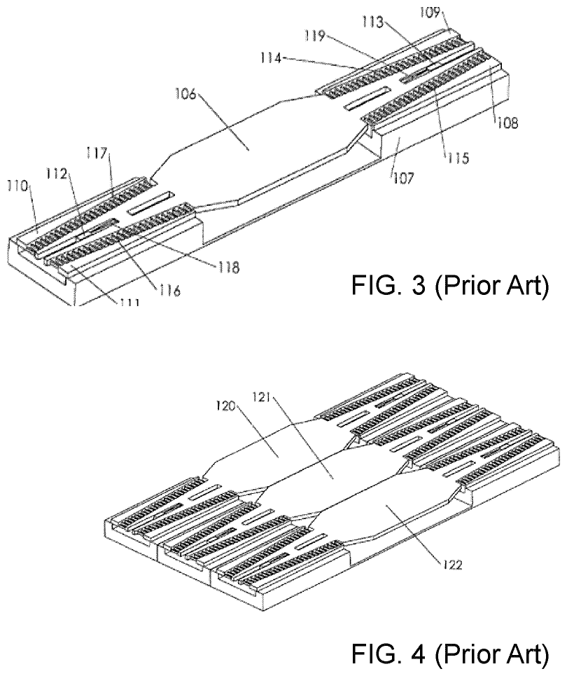

MEMS Micromirrors and Micromirror Arrays referred to in the present disclosure may include, but are not limited to, those in US patents U.S. Pat. Nos. 7,535,620, 7,911,672, 8,238,018, 8,472,105, 9,036,231 and 10,551,613. Prior art MEMS micromirrors and micromirror arrays are shown in FIGS. 1A, 1B, 2A, 2B, 3 and 4.

The term “fill factor” as used herein refers to mirror width divided by distance between two adjacent mirror centers.

Optical apertures implemented in the present systems and methods may have dimensions of about 5×5 mm or greater, and preferably may be 10×10 mm or greater.

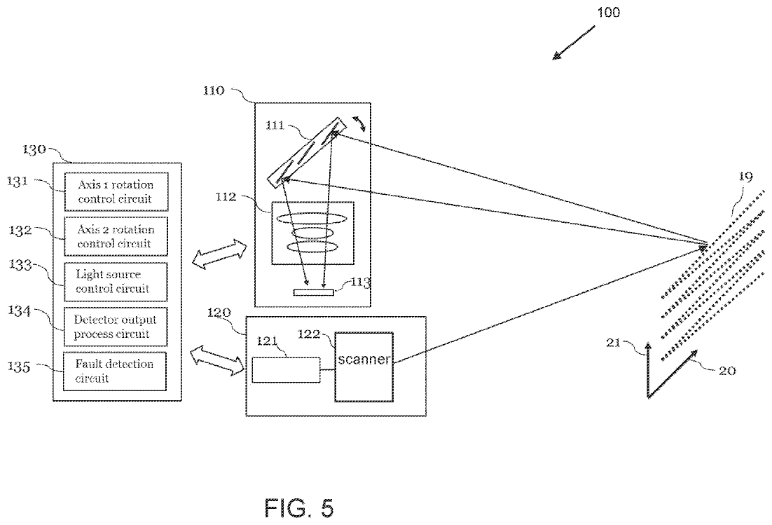

FIG. 5 shows an example of a LiDAR system 100 comprising a high fill factor MEMS mirror array 111. The system may further comprise a light emitting unit 120, a light receiving unit 110 and a control unit 130. These three components (110, 120, 130) may be in optical communication with one another. Each mirror in the mirror array 111 may be independently or collectively movable between any position within a predefined scanning range. The mirror array 111 may have a fill factor of about 75% or higher, and preferably of about 99% or higher. The emitting unit 120 may comprise a light source 121 and a scanner 122. The light emitted from the light source 121 may be coupled to the scanner 122. The emitting of light by the emitting unit 120 may be controlled by a light source control circuit 133 with time dependent modulation. The modulation may be pulsed or continual.

The MEMS mirror array 111 may include either one dimensional (“1D”) or two dimensional (“2D”) rotational micromirrors. The MEMS mirror controller may be configured differently depending on whether 1D or 2D rotational micromirrors are implemented. Under the control of axis 1 rotation control circuit 131 and axis 2 rotation control circuit 132, the scanner 122 may redirect incident light to a scanning target 19 according to a raster scanning pattern. The pattern may be composed by a fast scan axis 20 and slow scan axis 21. The two axes may be orthogonal, acute angled, or other patterns. The light receiving unit 110 may comprise a high fill factor MEMS mirror array 111, a focusing lens system 112 and a photon signal detector 113. A fraction of reflected light emitted from the emitting unit 120 after bouncing from target 19 may be recollected by the unit. The high fill factor MEMS mirror array 111 may comprise one or more sets of mirrors and MEMS actuator(s). Each mirror element in the mirror array may be actuated independently or collectively, depending on the scenario. The MEMS mirror positions may be controlled by either one or both 131 and 132 rotation control circuit. With the high fill factor MEMS mirror array 111, returning light may be deflected to a focusing lens system 112 that focuses the returning light onto the photon detector 113. The photosensitive detector 113 may be coupled to a detector output processing controlling unit 134 in the control unit 130. A fault detection circuit 135 may be included in or in communication with the control unit 130 to detect light source failure, scanning system failure, receiving mirror array failure and/or detector operation failure.

The fault detection circuit 135 may transform into electronic signals, for analysis, variables related to the positions of the scanning MEMS mirror and photon receiving MEMS mirrors. The transformation into electronic signals may be through, e.g., optical sensing or electrical sensing (e.g., piezoresistive, piezoelectric or capacitive sensing). The fault detection circuit 135 may detect the mirror integrity and whether the mirrors are functionally as intended. The fault detection circuit 153 may monitor mirror working conditions (e.g., changes in environmental parameters such as, for example, temperature, shock and vibration) and thereby may determine whether the mirror is working in a favorable environment and/or provide information to the rotation control circuits for suitable control adjustments.

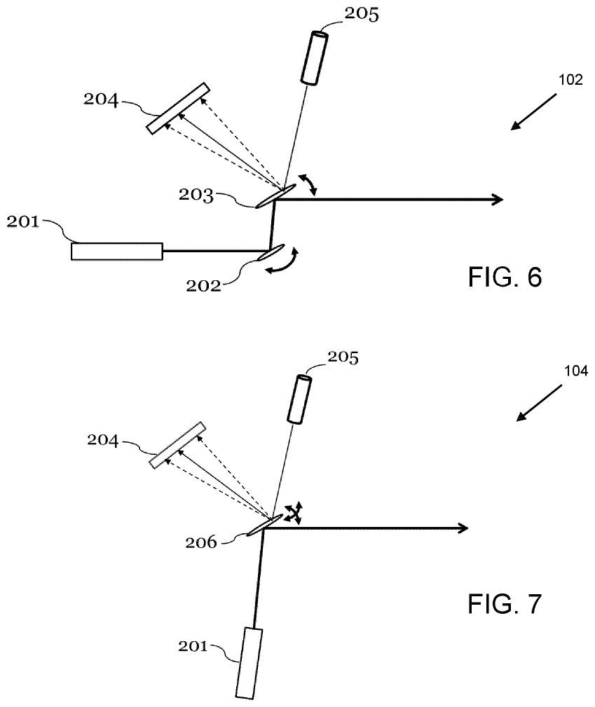

FIGS. 6, 7, 8 and 9 are schematic diagrams showing several example configurations 102, 104, 106 and 108, respectively, of the light source 121 and scanner 122.

In some embodiments (see FIG. 6), the light source 121 may be a collimated single wavelength pulsed or continuously modulated laser source 201. The laser may be an external laser device coupled by an optical fiber or an integrated laser diode module. The emitting light beam may be coupled to a first single axial scanning mirror 202 and the mirror may be either galvanometer or MEMS scanning mirror. After the first mirror 202, the light beam may be coupled to second single axial mechanical scanning mirror 203 and the mirror may be either galvanometer or MEMS scanning mirror. The scanning axial of the two mirrors can be angled or orthogonal but not parallel. The second mirror 203 may be coupled to an angle detection setup that comprises a light source 205 and an optical position sensor 204. The light source 205 may emit a detectable beam that is deflected by the second mirror 203 and detected by the optical position sensor 204. The rotation angle of the mirror 203 may be related to the beam position on optical sensor 204. The positions of MEMS mirror 202 and 203 can also be sensed by electrical sensors using on chip electrical sensing (e.g., piezoresistive, piezoelectric or capacitive sensing) elements. Data from the position sensor 204 or other electrical sensors may be sent to the control unit 130 for fault detection.

In some embodiments (see FIG. 7), the light source 121 may be a collimated single wavelength pulsed or continuously modulated laser source 201. The laser may be an external laser device coupled by an optical fiber or an integrated laser diode module. The emitting laser beam may be coupled to a dual axis mechanical scanning mirror 206 which may be either a galvanometer or a MEMS scanning mirror. The mirror 206 may be coupled to an angle detection setup that comprises a light source 205 and optical position sensor 204. The light source 205 may emit a detectable beam that is deflected by the mirror 206 and the optical position sensor 204. The rotation angle of the two mirror (206) axes may be related to the beam position on the optical sensor 204. The positions of MEMS mirror 206 can also be sensed by electrical sensors using on chip electrical sensing (e.g., piezoresistive, piezoelectric or capacitive sensing) elements. Data from the optical position sensor 204 or other electrical sensors may be sent to the control unit 130 for fault detection.

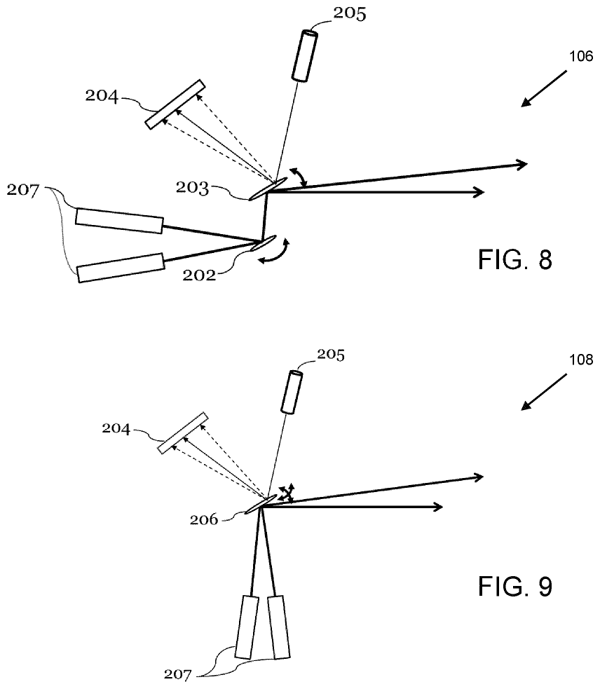

In some embodiments, as shown in FIG. 8, the light source 121 may comprise more than one collimated single wavelength pulsed or continuously modulated laser sources 207. The laser may be an external laser device coupled by an optical fiber or an integrated laser diode module. The emitting laser beam may be coupled to a first single axial scanning mirror 202 which may be either a galvanometer or a MEMS scanning mirror. After the mirror 202, the laser beam may be coupled to second single axial scanning mirror 203 which may be either galvanometer or a MEMS scanning mirror. In the example shown in FIG. 8, the two laser beams may be at an angle with respect to one another. Incident beams may be in the same plane, or substantially in the sample plane. The scanning axial of the two mirrors 202 and 203 can be angled or orthogonal but not parallel. The scanning range for the axis for the corresponding mirror may be increased by the laser modules when several beams, covering multiple areas, are used. The second mirror 203 may be coupled to an angle detection setup comprising a light source 205 and an optical position sensor 204. The light source 205 may emit a detectable beam that is deflected by the second mirror 203 and by the optical position sensor 204. The rotation angle of the second mirror 203 may be related to the beam position on the sensor 204. The positions of MEMS mirror 203 can also be sensed by electrical sensors using on chip electrical sensing (e.g., piezoresistive, piezoelectric or capacitive sensing) elements. Data from the position sensor 204 or other electrical sensors may be sent to the control unit 130 for fault detection.

In other embodiments (FIG. 9), the light source 121 may comprise more than one collimated single wavelength pulsed or continuously modulated laser sources 207 with identical or nearly identical wavelength. The laser may be an external laser device coupled by an optical fiber or an integrated laser diode module. The emitting laser beam is coupled to a dual axial mechanical scanning mirror 206 and the mirror may be either galvanometer or a MEMS scanning mirror. In the example shown in FIG. 9, the two laser beams may be at an angle with respect to one another. Incident beams may be in the same plane, or substantially in the sample plane. The scanning range for the axis may be multiplied by the use of several laser beams. The mirror 206 is coupled to an angle detection setup that comprises a light source 205 and an optical position sensor 204. The light source 205 emits a detectable beam that get deflected by mirror 206 and detected by the optical position sensor 204. The rotation angles of two mirror axis are related to the beam position on the optical sensor 204. The positions of the MEMS mirror 206 can also be sensed by electrical sensors using on chip electrical sensing (e.g., piezoresistive, piezoelectric or capacitive sensing) elements. Data from the position sensor 204 or other electrical sensors may be sent to the control unit 130 for fault detection.

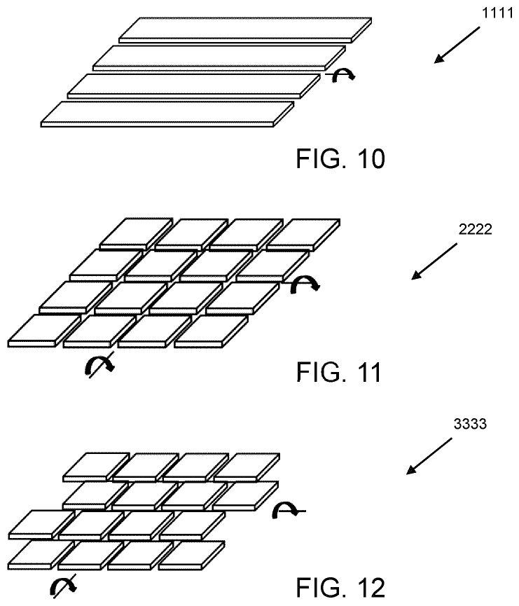

FIGS. 10-12 show several example embodiments of high fill factor MEMS mirror arrays that may be used in the system 100. In FIG. 10, a MEMS mirror array 1111 is shown wherein each individual mirror in the array is defined by a long edge and short edge and mirrors are placed paralleled to each other along the long edge. The rotation axis is parallel to long edge. Rotation of the mirrors may be controlled independently or collectively. In mirror arrays 2222 and 3333, shown in FIGS. 11 and 12, respectively, the individual mirrors are arranged in an array along two directions that may be angled or orthogonal, and collectively form a 2D mirror array. The shape of the individual mirrors may be, e.g., rectangular, circular or hexagonal. Each mirror has two rotation axes that may be controlled independently or collectively.

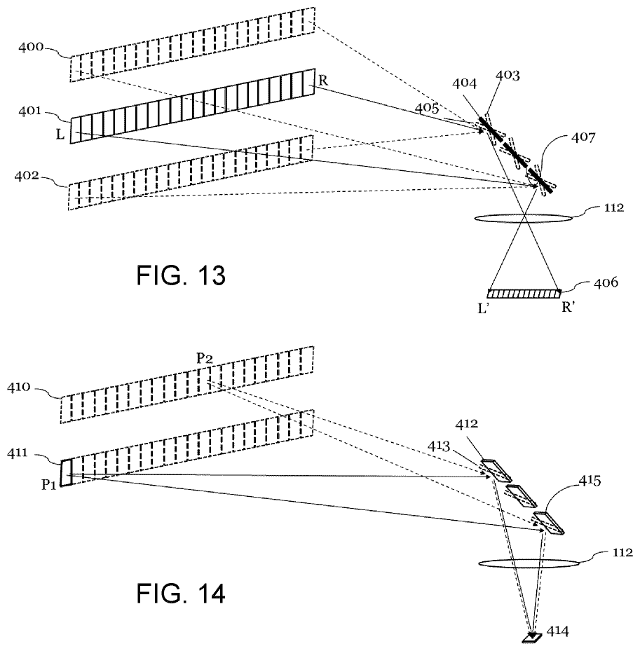

FIG. 13 illustrates the working principle of the light receiving unit 110 when a single axis MEMS mirror array is used for light receiving. The system comprises a single axis high fill factor MEMS mirror array 407, focusing lens 112 and an optical photon detector 406. This detector 406 may be a long single detector or a 1D detector array. Three scanning lines 400, 401, 402 may be projected by the light emitting unit 120 onto a target (not shown) at different positions. The individual mirrors in the high fill factor mirror array 407 may be controlled synchronously to rotate to a same angle at a certain time. Mirror positions 403, 404, 405 correspond to the three scanning lines 400, 401, 402, respectively. Each scanning line may be imaged by focusing the scanning line, with the lens system 112, onto the detector 406. In other words, light reflected from a certain position on the target is received, or detected at a corresponding position on the detector when the mirror array 407 is in the appropriate position. For example, taking the single scanning line 401 into consideration, the reflected photons from the L position reaches the mirror array 407 and is deflected to the lens 112. L is then imaged on the detector 406 at the L′ position. Similarly, the reflected photons from R position reaches the mirror array, is deflected to lens 112, and R is then imaged on the detector 406 at the R′ position.

FIG. 14 illustrates the working principle of the light receiving unit 110 when a dual axis high fill factor MEMS mirror array is used for light receiving. The system 100 comprises a dual axis MEMS mirror array 415, focusing lens 112 and an optical photon detector 414. The detector 414 may be, for example, a single photon detector. The light emitting unit 120 may project light onto different scanning areas, e.g., areas 410 and 411, on the target surface (not shown). The elementary dual axis mirrors in the mirror array 415 may be controlled synchronously and may rotate to a same angle at a certain time. In this example embodiment, mirror positions 412 and 413 correspond to scanning points P1 and P2, respectively. In other words, the main axis of the focusing optics may be deflected to a corresponding position on the detection target for a given position, or extent of rotation in the two axes, of the mirrors in the mirror array 407. For example, to image the point P1, the reflected photons from P1 reaches the mirror array 407 and is deflected to the lens 112, and in turn, is imaged on detector 414. Similarly, the reflected photons from the P2 position reaches the mirror array 407 and is deflected to the lens 112 and P2, in turn, is also imaged on the detector 414.

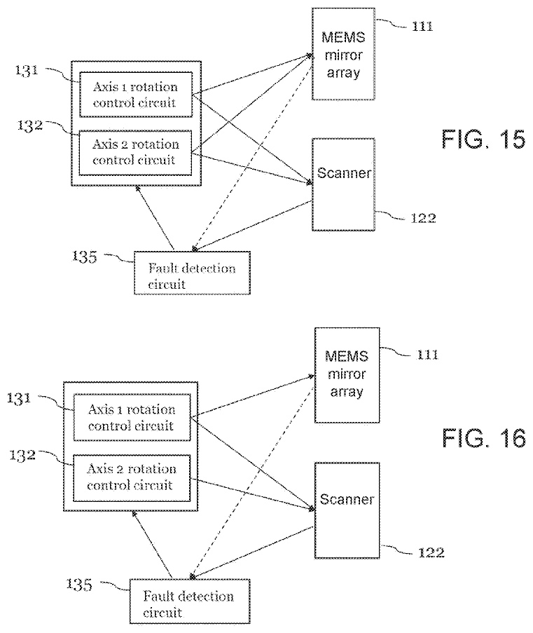

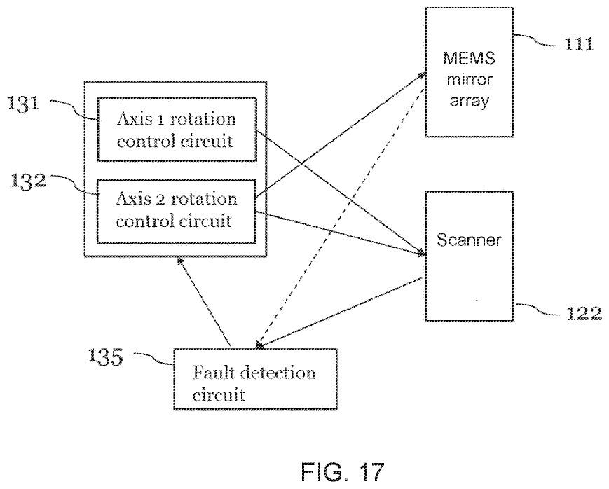

FIGS. 15-17 show an exemplary coupling topology of scanner 122 and MEMS mirror array 111 with axis 1 rotation control circuit 131, axis 2 rotation control circuit 132 and fault detection circuit 135. In one of the embodiments (FIG. 15), scanner 122 may be controlled by control circuits 131 and 132 for dual axis beam scanning. The MEMS mirror array 111 may also be controlled by control circuits 131 and 132 for dual axis scanning. The control signal for both 111 and 122 may be synchronized or substantially synchronized in frequency and phase, but signal amplitude may vary. The scanner 122 may provide feedback signal regarding scanner position for both rotation axes to the fault detection circuit 135. Meanwhile, the fault detection circuit 135 may process the signal and send commands to both of the control circuits 131 and 132 to ensure or substantially ensure the proper function of the scanner 122 and its synchronization rotations with MEMS mirror array 111. Optionally, the MEMS mirror array 111 may provide feedback signal regarding MEMS mirror array position to the fault detection circuit 135. Meanwhile, the fault detection circuit 135 may process the signal and send commands to both of the circuits 131 and 132 to ensure or substantially ensure the proper function of MEMS mirror array 111 and its synchronization rotations with scanner 122. In another two example embodiments, shown in FIGS. 16 and 17, the scanner 122 may be under control of the circuits 131 and 132 for dual axis beam scanning. The MEMS mirror array 111 may be under control of either one of the circuits 131 and 132 for single axis scanning. The control signal for the shared controlling circuit by 111 and 122 may be synchronized or substantially synchronized in frequency and phase, but signal amplitude may vary. The scanner 122 may provide feedback signal regarding scanner position for both rotation axes to the fault detection circuit 135. Meanwhile, the fault detection circuit 135 may process the signal and send commands to both of the circuits 131 and 132 to ensure or substantially ensure the proper function of scanner 122 and its synchronization rotations with MEMS mirror array 111. Optionally, MEMS mirror array 111 may provide feedback signal regarding MEMS mirror array position to the fault detection circuit 135. Meanwhile, the fault detection circuit 135 may process the signal and send commands to both of the circuits 131 and 132 to ensure or substantially ensure the proper function of the MEMS mirror array 111 and its synchronization rotations with scanner 122.

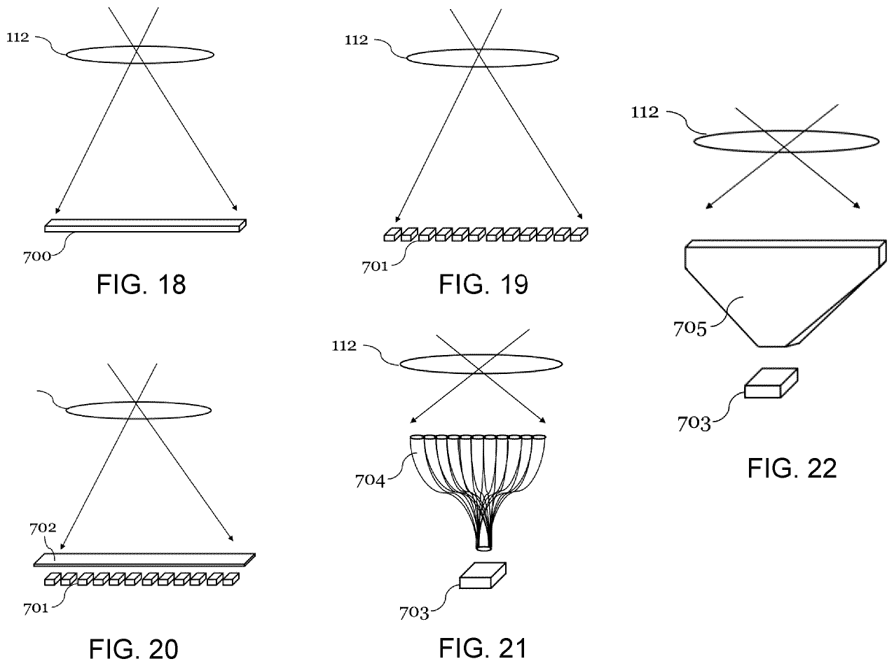

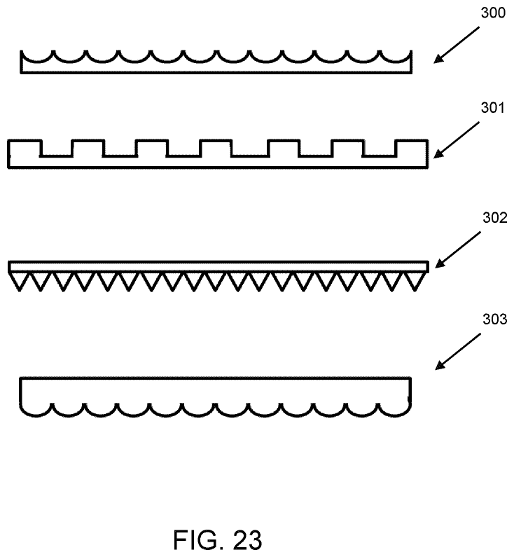

FIGS. 18-22 are schematic diagrams showing different example embodiments of configurations of the lens system 112 and the photosensitive detector 113. In the example embodiment shown in FIG. 7, the photon sensitive detector 113 may be single detector 700 with a long edge and a short edge and the detector may be coupled to the detector output process circuit 134. The detector 700 may sense the incident photons and send a signal to process circuit 134. In another example embodiment (FIG. 19), the photosensitive detector 113 may be a 1D detector array 701 with multiple photosensitive detecting pixels. Each pixel may detect incident photons and send signals to the process circuit 134 independently. In another example embodiment (FIG. 20), the photosensitive detector 113 may comprise a 1D detector array 701 with multiple detecting pixels and an optical diffusing device 702. Each pixel detect may detect incident photons and send signals to the process circuit 134 independently. Diffusing device (702) may avoid or reduce the likelihood of detection failure when photons radiate on the gaps between each detecting pixel. In FIG. 21, the photosensitive detector 113 comprises a photon detector 703 and an optic fiber bundle 704. As shown, one end of the fiber bundle 704 may face the lens 112 and the other end may face the detector 703. The incident photons may be collected by the lens 112 system, coupled to the fiber bundle 704, and then coupled to the detector 703. The 703 may sense the incident photons and send signals to the process circuit 134. In the example embodiment shown in FIG. 22, the photosensitive detector 113 comprises a photosensitive detector 703 and an optical waveguide 705. One end of the optical waveguide 705 may face the lens 112 and the other end may face the detector 703. The incident photons may be collected by the lens system 112, coupled to waveguide 705, and then coupled to detector 703. Detector 703 may sense the incident photons and send signals to the process circuit 134. FIG. 23 schematically illustrates five different example embodiments of optical diffusing devices (300,301,302,303) which may be used alternatively to, or in combination with the aforementioned optical diffusing devices. Diffusing devices other than those disclosed herein may be used.

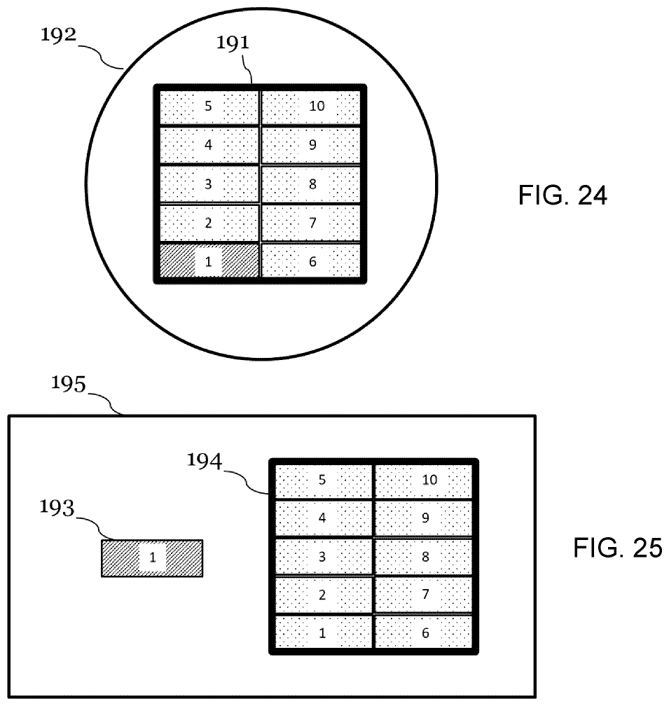

In some embodiments, a single MEMS mirror may be used in the scanner 112. In such embodiments, the MEMS mirror in scanner 112 and the MEMS mirror array 111 may be fabricated as one chip or packaged together, i.e., in the same chip package. FIG. 24 illustrates an example embodiment 192 whereby a single high fill factor MEMS mirror array 191 may be used for both light scanning and receiving. The MEMS mirror array 191 is a schematic illustration of an exemplary high fill factor mirror array comprising 10 individual mirrors (numbered 1-10). In some embodiments, the mirror 1 may be used for scanning and mirrors 2-10 may be used for light reception. Each of the mirrors 1-10 may be a single or dual axis mirror operable by external control signals from the control circuit 130. In some embodiments (FIG. 25), a single MEMS mirror 193 may be used for scanning, and a high fill factor MEMS mirror array 194 may be used for light reception. MEMS mirror 193 and MEMS mirror array 194 may be packaged together, i.e., in the same chip package. The mirror 193 and each of the mirrors (1-10) in the high fill factor mirror array 194 may be single or dual axis mirrors operable by external control signals from the control circuit 130.

TABLE 1
Example embodiments of MEMS 2D mirror specifications with independent x and y axis tilting.

| | | | X Axis | | Y Axis |
|---|---|---|---|---|---|
| | | X Axis Max | Resonant | Y Axis Max | Resonant |
| Chip ID | Mirror Size | Angle (FOV) | Frequency (Hz) | Angle (FOV) | Frequency (Hz) |
| 1 | 4.8 × 5.0 mm | >30 degrees | ~80 | >60 degrees | ~800 |
| | (oval) | | | | |
| 2 | 3 mm (circular) | >30 degrees | ~120 | >60 degrees | ~1,500 |
| 3 | 2 mm (circular) | >30 degrees | ~170 | >60 degrees | ~3,300 |
| 4 | 1 mm (circular) | >30 degrees | ~180 | >60 degrees | ~11,000 |
| 5 | 1X14 Mirror | >30 Degrees | >2 KHz | | |
| | Array, Each | | | | |
| | mirror | | | | |
| | size: 7 × 0.48 mm | | | | |
| | (rectangular); Fill | | | | |
| | factor: 99%; | | | | |
| | Optical aperture | | | | |
| | size: 7 × 7 mm | | | | |
| 6 | 1X14 Mirror | >30 Degrees | >2 KHz | | |
| | Array, Each | | | | |
| | mirror | | | | |
| | size: 10 × 0.48 mm | | | | |
| | (rectangular); Fill | | | | |
| | factor: 99%; | | | | |
| | Optical aperture | | | | |
| | size: 10 × 7 mm | | | | |

| Point-to-Point (quasi-static) or | Resonant Driving |
|---|---|
| Resonant Driving | |

For simplicity and clarity of diagram, where considered appropriate, reference numerals may be repeated among the figures to indicate corresponding or analogous elements. In addition, numerous specific details are set forth in order to provide a thorough understanding of the examples described herein. However, it will be understood by those of ordinary skill in the art that the examples described herein may be practiced without these specific details. In other instances, well-known methods, procedures and components have not been described in detail so as not to obscure the examples described herein. Also, the description is not to be considered as limiting the scope of the examples described herein.

It will be appreciated that the examples and corresponding diagrams used herein are for illustrative purposes only. Different configurations and terminology may be used without departing from the principles expressed herein. For instance, components and modules may be added, deleted, modified, or arranged with differing connections without departing from these principles.

The steps or operations in the flow charts and diagrams described herein are just for example. There may be many variations to these steps or operations without departing from the principles discussed above. For instance, the steps may be performed in a differing order, or steps may be added, deleted, or modified.

Although the above principles have been described with reference to certain specific examples, various modifications thereof will be apparent to those skilled in the art as outlined in the appended claims.

1. A light receiving unit configured to be used in a Light Detection and Ranging (LiDAR) system, the light receiving unit comprising:
a MEMS mirror array including a plurality of receiving mirrors, the MEMS mirror array being configured to deflect reflected photons, produced by a scanning unit, to a photon detector, the MEMS mirror array being controllable by a control system that is configured to control the scanning unit and the light receiving unit.

2. The light receiving unit of claim 1, further comprising the photon detector and a lens system for focusing the reflected photons on the photon detector.

3. The light receiving unit of claim 1, wherein positions of the MEMS mirror are detectable by electrical sensors using electrical sensing elements configured to send data to the control system.

4. The light receiving unit of claim 1, wherein the electrical sensing elements comprise piezoresistive, piezoelectric or capacitive sensing elements.

5. The light receiving unit of claim 1, further comprising a light diffusing device positioned between the lens system and the photon detector.

6. The light receiving unit of claim 1, wherein the light receiving unit is further configured to rotate the mirrors in the MEMS mirror array synchronously to a predefined angle at a predefined time to deflect photons reflected from one of the scanning lines.

7. The light receiving unit of claim 1, wherein the receiving mirrors are rotatable in one dimension (1D) and/or in two dimensions (2D), and are controllable by the control system to rotate independently or collectively.

8. The light receiving unit of claim 1, wherein the receiving mirrors of the MEMS mirror array are defined by a long edge and a short edge, and the mirrors are positioned parallel to one another along the long edge, a rotation axis of the MEMS mirror array is parallel to the long edge.

9. The light receiving unity of claim 1, wherein the receiving mirrors in the MEMS array are arranged in a 2D mirror array, and each of the mirrors has two rotation axes.

10. A Light Detection and Ranging (LiDAR) system, comprising:
a light emitting unit comprising a light source comprising one or more laser emitters for generating one or more laser beams for producing reflected photons off of a target;
a scanning unit comprising a scanning mirror for changing an outgoing direction of the one or more laser beams;
a light receiving unit comprising a MEMS mirror array including a plurality of receiving mirrors and a photon detector, the MEMS mirror array being configured to deflect the reflected photons to the photon detector; and
a control system for controlling the LiDAR system, the control system being configured to adjust the scanning and receiving mirrors.

11. The LiDAR system of claim 10, wherein the control system comprises:
at least one of a first axis control circuit and a second axis control circuit for adjusting the scanning and receiving mirrors;
a light source control circuit configured to control the light emitting unit to modulate the one or more laser beams;
a detector output process circuit configured to receive signals from the photon detector; and
a fault detection circuit configured to detect failure of the scanning unit, of the light receiving unit and/or of the photon detector.

12. The LiDAR system of claim 10, wherein the scanning mirror is a MEMS mirror.

13. The LiDAR system of claim 10, wherein positions of the MEMS mirror are detectable by electrical sensors using electrical sensing elements configured to send data to the control system.

14. The LiDAR system of claim 10, wherein the scanning mirror is a galvanometer-based scanning mirror.

15. The LiDAR system of claim 10, wherein the scanning unit further comprises an angle detection system comprising a second light source and a position sensor, wherein the second light source is configured to emit a detectable laser beam that is deflected by the scanning mirror and detected by the position sensor to obtain mirror position data, the position sensor being configured to send the mirror position data to the control system.

16. The LiDAR system of claim 10, wherein the scanning unit further comprises a second scanning mirror for directing the one or more laser beams to the scanning mirror.

17. The LiDAR system of claim 10, wherein the scanning and receiving mirrors are rotatable in one dimension (1D) and/or in two dimensions (2D), and are controllable by the control system to rotate independently or collectively.

18. The LiDAR system of claim 10, wherein the receiving mirrors of the MEMS mirror array are defined by a long edge and a short edge, and the mirrors are positioned parallel to one another along the long edge, a rotation axis of the MEMS mirror array is parallel to the long edge.

19. The LiDAR system of claim 10, wherein the receiving mirrors in the MEMS array are arranged in a 2D mirror array, and each of the mirrors has two rotation axes.

20. The LiDAR system of claim 18, wherein the scanning unit is configured to project a plurality of scanning lines onto a target.

21. The LiDAR system of claim 19, wherein the scanning unit is configured to project photons onto a plurality of scanning areas to detect a plurality of scanning points in each of the scanning areas.

22. The LiDAR system of claim 1, wherein the fault detection circuit is configured to receive and send to, in the form of electronic signals, the first axis control circuit and/or second axis control circuit, values corresponding to positions of the mirrors and/or environmental conditions including one or more of temperature, shock, and vibration, to enable the first and/or second axis control circuit to adjust the positions of the mirrors based on the values.

23. The LiDAR system of claim 1, further comprising a lens system configured to direct the reflected photons to the photon detector, and a light diffusing device positioned between the lens system and the photon detector.

24. The LiDAR system of claim 13, wherein the scanning MEMS mirror is part of the MEMS mirror array.

25. The LiDAR system of claim 13, wherein the scanning MEMS mirror is separate from the MEMS mirror array.

26. The LiDAR system of claim 13, wherein the scanning MEMS mirror and the MEMS mirror array are packaged together.
